(19) United States
(12) Patent Application Publication
(10) Pub. No.: US 2025/0351447 A1
(43) Pub. Date: Nov. 13, 2025

(54) SEMICONDUCTOR STRUCTURE AND FABRICATION METHOD THEREOF

(71) Applicant: Semiconductor Manufacturing International (Shanghai) Corporation, Shanghai (CN)

(72) Inventor: Jisong JIN, Shanghai (CN)

(21) Appl. No.: 18/774,102

(22) Filed: Jul. 16, 2024

(30) Foreign Application Priority Data
May 8, 2024 (CN) 202410566961.2

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/018

(57) ABSTRACT

A semiconductor structure and a fabrication method of the semiconductor structure are provided in the present disclosure. The method includes providing a base substrate, where a stacked layer structure, including sacrificial layers and channel layers, and a dummy gate structure are formed on the base substrate; forming a source-drain doped layer on the base substrate; removing the dummy gate structure to form a gate opening; removing the sacrificial layers to form through-grooves and a channel layer structure including the channel layers spaced apart from each other; forming inner spacers in the source-drain doped layer; and forming a gate structure crossing the channel layer structure in the gate opening and the through-grooves. The gate structure surrounds the channel layers; and the gate structure between adjacent channel layers and between the channel layer structure and the base substrate is spaced apart from the source-drain doped layer by the inner spacers.

### CROSS-REFERENCE TO RELATED APPLICATION

This application claims the priority of Chinese Patent Application No. 202410566961.2, filed on May 8, 2024, the content of which is incorporated herein by reference in its entirety.

### TECHNICAL FIELD

The present disclosure generally relates to the field of semiconductor manufacturing and, more particularly, relates to a semiconductor structure and a fabrication method thereof.

### BACKGROUND

In semiconductor manufacturing, with the development trend of very large-scale integrated circuits, the feature sizes of integrated circuits continue to decrease. In order to adapt to smaller feature sizes, the channel lengths of metal-oxide-semiconductor field-effect transistors (MOSFET) have also been reduced accordingly. However, as the device channel length is reduced, the distance between the source electrode and the drain electrode of the device may also be reduced. Therefore, the gate structure's ability to control the channel may become worse, and it may be increasingly difficult for the gate voltage to pinch off the channel, which may result in subthreshold leakage phenomenon. That is, so-called short-channel effects (SCE) may be more likely to occur.

Therefore, in order to better adapt to the requirements of scaling down device sizes, semiconductor processes have gradually begun to transition from planar transistors to three-dimensional transistors with higher efficiency, such as gate-all-around (GAA) transistors. In the gate-all-around metal gate transistor, the gate may surround the region where the channel is located from all sides. Compared with planar transistors, the gate of the gate-all-around metal gate transistor may have stronger control over the channel and better suppress the short channel effect.

### SUMMARY

One aspect of the present disclosure provides a semiconductor structure. The semiconductor structure includes a base substrate; a channel layer structure, disposed above the base substrate, where the channel layer structure includes one or more channel layers spaced apart from each other; a gate structure, on the base substrate and crossing the channel layer structure, where the gate structure surrounds the one or more channel layers along an extension direction of the gate structure; and a gate structure between adjacent channel layers and between the channel layer structure and the base substrate is configured as a stacked layer gate; a source-drain doped layer, on the base substrate at two sides of the gate structure and in contact with an end of the channel layer structure; and inner spacers, at a sidewall of the stacked layer gate and embedded in the source-drain doped layer, where the stacked layer gate and the source-drain doped layer are spaced apart by the inner spacers.

Optionally, the sidewall of the stacked layer gate is coplanar with a sidewall of a channel layer.

Optionally, along an extension direction of the channel layer structure, a dimension of the inner spacers embedded in the source-drain doped layer is from about 1 Å to about 50 Å.

Optionally, the inner spacers include air spacers, dielectric spacers, and/or a combination thereof.

Another aspect of the present disclosure provides a fabrication method of a semiconductor structure. The method includes providing a base substrate, where a stacked layer structure is formed on the base substrate and includes sacrificial layers and channel layers alternately stacked from a bottom to a top along a vertical direction; and a dummy gate structure is further formed on the base substrate crossing the stacked layer structure and covers sidewalls and a top of the stacked layer structure; forming a source-drain doped layer on the base substrate at two sides of the dummy gate structure, where the source-drain doped layer is in contact with an end of the stacked layer structure; removing the dummy gate structure to form a gate opening; removing the sacrificial layers of the stacked layer structure to form through-grooves and a channel layer structure, where the channel layer structure includes the channel layers which are spaced apart from each other, and the through-grooves expose the source-drain doped layer; forming inner spacers in the source-drain doped layer exposed by the through-grooves; and forming a gate structure crossing the channel layer structure in the gate opening and the through-grooves, where the gate structure surrounds the channel layers along an extension direction of the gate structure; and the gate structure between adjacent channel layers and between the channel layer structure and the base substrate is spaced apart from the source-drain doped layer by the inner spacers.

Optionally, the gate structure crossing the channel layer structure is formed in the gate opening and the through-grooves, such that sidewalls of the gate structure between adjacent channel layers and between the channel layer structure and the base substrate are coplanar with sidewalls of the channel layers.

Optionally, forming the inner spacers in the source-drain doped layer exposed by the through-grooves includes along an extension direction of the channel layer structure, removing a part of the source-drain doped layer via the through-grooves, and forming grooves connected to the through-grooves and extending into the source-drain doped layer; and retaining a space of the grooves to form air spacers configured as the inner spacers; or forming dielectric spacers in the grooves as the inner spacers.

Optionally, along the extension direction of the channel layer structure, the part of the source-drain doped layer is removed via the through-grooves, and the grooves connected to the through-grooves and extending into the source-drain doped layer are formed, such that a dimension of the removed part of the source-drain doped layer is about 1 Å to 50 Å along the extension direction of the channel layer structure.

Optionally, using an isotropic etching process, along the extension direction of the channel layer structure, the part of the source-drain doped layer is removed via the through-grooves, and the grooves connected to the through-grooves and extending into the source-drain doped layer are formed.

Optionally, for removing the part of the source-drain doped layer via the through-grooves along the extension direction of the channel layer structure, an etching selectivity ratio between the source-drain doped layer and the channel layers is greater than or equal to 10.

Optionally, forming the inner spacers in the source-drain doped layer exposed by the through-grooves includes forming the dielectric spacers in the grooves as the inner sidewalls; and forming the dielectric spacers in the grooves includes forming a dielectric material layer covering a bottom and sidewalls of the gate opening and filling the through-grooves and the grooves; and includes removing the dielectric material layer covering the bottom and the sidewalls of the gate opening and in the through-grooves and retaining the dielectric material layer in the grooves as the dielectric spacers.

Optionally, an atomic layer deposition process is configured to form the dielectric material layer covering the bottom and the sidewalls of the gate opening and filling the through-grooves and the grooves.

Optionally, an isotropic etching process is configured to remove the dielectric material layer covering the bottom and the sidewalls of the gate opening and the through-grooves.

Optionally, for removing the dielectric material layer covering the bottom and the sidewalls of the gate opening and the through-grooves, an etching selectivity ratio between the dielectric material layer and the channel layers is greater than or equal to 10.

Optionally, for removing the sacrificial layers of the stacked layer structure to form the through-grooves, an etching selectivity ratio between the sacrificial layers and the source-drain doped layer is greater than or equal to 10, and an etching selectivity ratio between the sacrificial layers and the channel layers is greater than or equal to 10.

Optionally, an epitaxial growth process is configured to form the source-drain doped layer on the base substrate at two sides of the dummy gate structure.

Optionally, in a step of providing the base substrate, the channel layers are made of a material including silicon, germanium, silicon germanium or a group III-V semiconductor material; and the sacrificial layers are made of silicon germanium.

Compared with the existing technology, the technical solutions provided by the present disclosure may achieve at least the following beneficial effects.

In the semiconductor structure provided by embodiments of the present disclosure, the inner spacers may be on the sidewalls of the stacked layer gate and embedded in the source-drain doped layer; and the stacked layer gate and the source-drain doping layer may be spaced apart by the inner spacers. In embodiments of the present disclosure, the inner spacers may be embedded in the source-drain doped layer, which may be beneficial for increasing the occupied space of the stacked layer gate, thereby improving the channel control capability of the stacked layer gate on the channel layer. Moreover, the inner spacers may be embedded in the source-drain doped layer, such that during the fabrication process of the semiconductor structure, the source-drain doped layer may be grown first, and then the inner spacers may be formed in the source-drain doped layer. Compared with the solution of forming the inner spacers first, and then growing the source-drain doped layer based on the inner spacers and the channel layers, the solution provided in the present disclosure may be beneficial for avoiding the difficulty of growth based on the inner spacers which may result in the fabrication of grain boundary in the source-drain doped layer to affect the stress, thereby being beneficial for improving the growth quality of the source-drain doped layer, ensuring the performance of the source-drain doped layer, and further being beneficial for improve the working performance of the semiconductor structure.

In the fabrication method of the semiconductor structure provided by embodiments of the present disclosure, the stacked layer structure may be formed on the base substrate and include sacrificial layers and channel layers alternately stacked from a bottom to a top along the vertical direction; the source-drain doped layer may be formed on the base substrate at two sides of the dummy gate structure, where the source-drain doped layer may be in contact with the end of the stacked layer structure along the extension direction of the stacked layer structure; the dummy gate structure may be removed to form the gate opening; the sacrificial layers of the stacked layer structure may be removed to form through-grooves, and the through-grooves may expose the source-drain doped layer; and the inner spacers may be formed in the source-drain doped layer exposed by the through-grooves. In embodiments of the present disclosure, the source-drain doped layer may be first grown based on the sidewalls of the stacked layer structure, and the inner spacers may be then formed. Compared with the solution of forming the inner spacers first, and then growing the source-drain doped layer based on the inner spacers and the channel layers, the solution provided in the present disclosure may be beneficial for avoiding the difficulty of growth based on the inner spacers which may result in the fabrication of grain boundary in the source-drain doped layer to affect the stress, thereby being beneficial for improving the growth quality of the source-drain doped layer, ensuring the performance of the source-drain doped layer, and further being beneficial for improve the working performance of the semiconductor structure.

### BRIEF DESCRIPTION OF THE DRAWINGS

The following drawings are merely examples for illustrative purposes according to various disclosed embodiments and are not intended to limit the scope of the present disclosure.

FIGS. 1-3 illustrate structural schematics corresponding to certain stages of an exemplary fabrication method of a semiconductor structure.

FIGS. 4-5 illustrate structural schematics of an exemplary semiconductor structure according to various disclosed embodiments of the present disclosure.

FIG. 6 illustrates a structural schematic of another exemplary semiconductor structure according to various disclosed embodiments of the present disclosure.

FIGS. 7-14 illustrate structural schematics corresponding to certain stages of an exemplary fabrication method of a semiconductor structure according to various disclosed embodiments of the present disclosure.

FIGS. 15-17 illustrate structural schematics corresponding to certain stages of another exemplary fabrication method of a semiconductor structure according to various disclosed embodiments of the present disclosure.

FIG. 18 illustrates a flowchart of an exemplary fabrication method of a semiconductor structure according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A semiconductor structure and a fabrication method of the semiconductor structure are provided in the present disclosure. The method includes providing a base substrate, where a stacked layer structure, including sacrificial layers and channel layers, and a dummy gate structure are formed on the base substrate; forming a source-drain doped layer on the base substrate; removing the dummy gate structure to form a gate opening; removing the sacrificial layers to form through-grooves and a channel layer structure including the channel layers spaced apart from each other; forming inner spacers in the source-drain doped layer; and forming a gate structure crossing the channel layer structure in the gate opening and the through-grooves. The gate structure surrounds the channel layers; and the gate structure between adjacent channel layers and between the channel layer structure and the base substrate is spaced apart from the source-drain doped layer by the inner spacers.

The working performance of existing semiconductor structures needs to be improved. Poor working performance of existing semiconductor structure is analyzed based on a fabrication method of a semiconductor structure hereinafter.

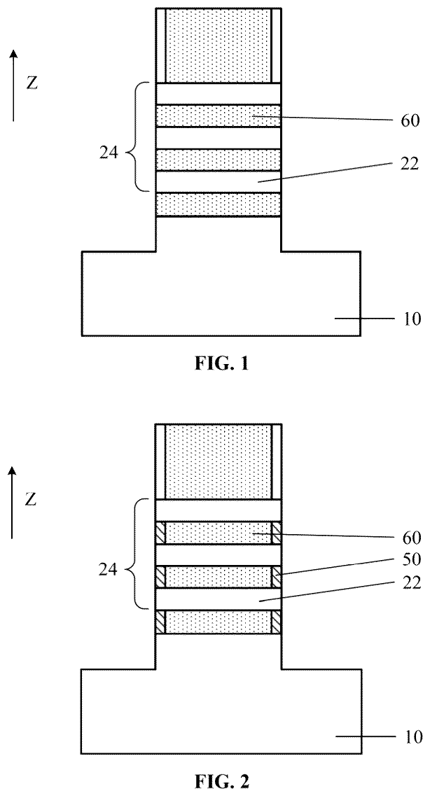

FIGS. 1-3 illustrate structural schematics corresponding to certain stages of an exemplary fabrication method of a semiconductor structure.

Referring to FIG. 1, a base substrate 10 may be provided; a channel layer structure 24 may be disposed above the base substrate 10; the channel layer structure 24 may include one or more channel layers 22 spaced apart along the vertical direction (as shown as the Z direction in FIG. 1); and a dummy gate structure 60, crossing the channel layer structure 24 and surrounding the channel layer 22, may be also formed on the base substrate 10.

Referring to FIG. 2, along exposed sidewalls of the channel layer structure 24, a part of the dummy gate structure 60 between channel layers 22 vertically adjacent to each other and between the channel layer structure 24 and the base substrate 10 may be removed to form grooves; and inner spacers 50 may be formed in the grooves.

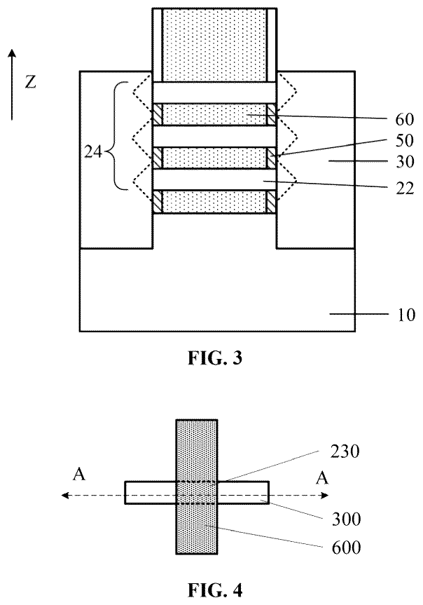

Referring to FIG. 3, a source-drain doped layer 30 may be formed on the base substrate 10 on two sides of the dummy gate structure 60; and the source-drain doped layer 30 may be in contact with the end of the channel layer structure 24 and the inner spacer 50.

When forming the source-drain doped layer 30, the end of the channel layer structure 24 and the inner spacer 50 may be configured as the base surface for growth. However, the growth based on the inner spacer 50 may be difficult, which may easily lead to the fabrication of grain boundary in the source-drain doped layer 30 (as shown by the dotted line in FIG. 3), thereby affecting the stress. Particularly, the inner spacer 50 may be configured to isolate the gate structure subsequently formed at the position of the dummy gate structure 60 and the source-drain doped layer 30. The inner spacers 50 may be made of a dielectric material. Therefore, the quality of the source-drain doped layer 30 grown based on the inner spacer 50 may be poor, thereby being difficult to ensure the performance of the source-drain doped layer 30 and further affecting the working performance of the semiconductor structure.

In order to solve above-mentioned technical problems, embodiments of the present disclosure provide a fabrication method of a semiconductor structure. The fabrication method may include providing a base substrate, where a stacked layer structure may be formed on the base substrate, the stacked layer structure may include sacrificial layers and channel layers which are stacked alternately from bottom to top along the vertical direction, and a dummy gate structure may be also formed on the base substrate crossing the stacked layer structure and cover the sidewalls and the top of the stacked layer structure; forming a source-drain doped layer on the base substrate on two sides of the dummy gate structure, where the source-drain doped layers may be in contact with the end of the stacked layer structure; removing the dummy gate structure to form a gate opening; removing the sacrificial layers of the stacked layer structure to form through-grooves and a channel layer structure, where the channel layer structure includes the channel layers which are spaced apart from each other, and the through-grooves expose the source-drain doped layer; forming inner spacers in the source-drain doped layer exposed by the through-grooves; forming a gate structure crossing the channel layer structure in the gate opening and the through-grooves, where the gate structure may surround the channel layers along the extension direction of the gate structure; and the gate structure between adjacent channel layers and between the channel layer structure and the base substrate may be spaced apart from the source-drain doped layer by inner spacers.

In embodiments of the present disclosure, the source-drain doped layer may be first grown based on the sidewalls of the stacked layer structure, and then the inner spacers may be formed. Compared with the solution of forming the inner spacers first, and then growing the source-drain doped layer based on the inner spacers and the channel layers, the solution provided in the present disclosure may be beneficial for avoiding the difficulty of growth based on the inner spacers which may result in the fabrication of grain boundary in the source-drain doped layer to affect the stress, thereby being beneficial for improving the growth quality of the source-drain doped layer, ensuring the performance of the source-drain doped layer, and further being beneficial for improve the working performance of the semiconductor structure.

In order to clearly illustrate above-mentioned described objectives, features, and advantages of the present disclosure, various embodiments of the present disclosure are described in detail with reference to accompanying drawings hereinafter.

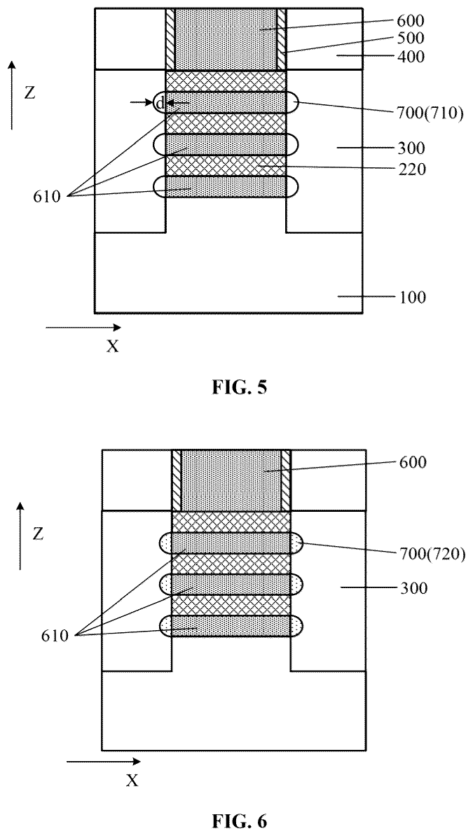

FIGS. 4-5 illustrate structural schematics of an exemplary semiconductor structure according to various disclosed embodiments of the present disclosure. FIG. 4 illustrates a top view of a gate structure, a channel layer structure, and a source-drain doped layer. FIG. 5 illustrates a cross-sectional view along an AA direction in FIG. 4.

Referring to FIGS. 4-5, a semiconductor structure may include a base substrate 100; a channel layer structure 230 disposed above the base substrate 100, where the channel layer structure 230 may include one or more channel layers 220 spaced apart along the vertical direction (shown as the Z direction in FIG. 5); a gate structure 600 on the base substrate 100 and crossing the channel layer structure 230, where the gate structure 600 may surround the channel layer 220 along the extension direction of the gate structure 600, and the gate structure 600 between adjacent channel layers 220 and between the channel layer structure 230 and the base substrate 100 may be configured as a stacked layer gate 610; a source-drain doped layer 300 on the base substrate 100 on two sides of the gate structure 600, where along the extension direction of the channel layer structure 230 (shown as the X direction in FIG. 5), the source-drain doped layer 300 may be in contact with the end of the channel layer structure 230; and inner spacers 700, on the sidewall of the stacked layer gate 610 and embedded in the source-drain doped layer 300, where the stacked layer gate 610 and the source-drain doped layer 300 may be separated by the inner spacers 700.

The base substrate 100 may provide process operation basis for the fabrication process of the semiconductor structure. Semiconductor structures may include gate-all-around (GAA) transistors and fork-sheet gate transistors.

In one embodiment, the base substrate 100 may be made of silicon. In other embodiments, the base substrate may also be made of other materials including germanium, silicon germanium, silicon carbide, gallium arsenide, indium gallium and/or the like. The base substrate may also be made of other types of substrates including a silicon-on-insulator substrate, a germanium-on-insulator substrate and/or the like. The material of the base substrate may be a material suitable for process needs or easy to integrate.

The channel layer structure 230 may include one or more channel layers 220 which are spaced apart along the vertical direction. The channel layer 220 may be configured as a transistor channel.

In one embodiment, the channel layer 220 may be made of a material including silicon, germanium, silicon germanium or group III-V semiconductor materials. Exemplarily, the channel layer 220 may be made of silicon. In other embodiments, the material of the channel layer may be determined based on the type and performance of the transistor.

The gate structure 600 may be configured to control the turn-on and turn-off of the channel of the transistor.

The gate structure 600 may surround and cover the channel layer 220. Therefore, the top, the bottom and the sidewalls of the channel layer 220 may all be configured as the channels, which may increase the area of the channel layer 220 configured as the channels, thereby increasing operating current of the semiconductor structure.

In one embodiment, the gate structure 600 may include a gate dielectric layer surrounding the channel layer 220 along the extension direction of the gate structure 600, and a gate electrode layer on the gate dielectric layer.

The gate dielectric layer may be configured to isolate the gate electrode layer and the channel layer 220, and isolate the gate electrode layer and the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the high-k gate dielectric layer may be made of a material including a high-k dielectric material. The high-k dielectric material may refer to a dielectric material with relative dielectric constant greater than relative dielectric constant of silicon oxide. In one embodiment, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In one embodiment, the gate structure 600 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may only include the work function layer.

In other embodiments, according to process requirements, the gate structure may also be a polysilicon gate structure.

In one embodiment, the sidewall of the stacked layer gate 610 may be coplanar with the sidewall of the channel layer 220.

The sidewall of the stacked layer gate 610 being coplanar with the sidewall of the channel layer 220 may be beneficial for increasing the coverage area of the channel layer 220 by the stacked layer gate 610 along the extension direction of the channel layer structure 230, thereby improving the control ability of the stacked layer gate 610 over the channel; and may also increase the area used as the channel in the channel layer 220, which may be beneficial for increasing the operating current of the semiconductor structure. Moreover, the sidewall of the stacked layer gate 610 being coplanar with the sidewall of the channel layer 220 may be beneficial for ensuring that the sidewall of the stacked layer gate 610 may be in the space of the inner spacer 700 in the source-drain doped layer 300, thereby ensuring the isolation effect of the inner spacer 700.

The source-drain doped layer 300 may be configured as the source region or drain region of the transistor. For example, the doped type of the source-drain doped layer 300 may be same as the channel conductivity type of the corresponding transistor.

The doped type of the source-drain doped layer 300 may be same as the channel conductivity type of the corresponding transistor. For example, when the base substrate 100 is configured to form an NMOS transistor, the doped ions in the source-drain doped layer 300 may be N-type ions, where N-type ions may include P ions, As ions or Sb ions; and when the base substrate 100 is configured to form a PMOS transistor, the doped ions in the source-drain doped layer 300 may be P-type ions, where the P-type ions may include B ions, Ga ions or In ions.

The inner spacer 700 may be configured to isolate the gate structure 600 and the source-drain doped layer 300 to reduce the parasitic capacitance between the gate structure 600 and the source-drain doped layer 300.

In one embodiment, the inner spacers 700 may be embedded in the source-drain doped layer 300, which may be beneficial for increasing the occupied space of the stacked layer gate 610, thereby improving the channel control capability of the stacked layer gate 610 on the channel layer 220. Moreover, the inner spacers 700 may be embedded in the source-drain doped layer 300, such that during the fabrication process of the semiconductor structure, the source-drain doped layer 300 may be grown first, and then the inner spacers 700 may be formed in the source-drain doped layer 300. Compared with the solution of forming the inner spacers first, and then growing the source-drain doped layer based on the inner spacers and the channel layers, the solution provided in the present disclosure may be beneficial for avoiding the difficulty of growth based on the inner spacers 700 which may result in the fabrication of grain boundary in the source-drain doped layer 300 to affect the stress, thereby being beneficial for improving the growth quality of the source-drain doped layer 300, ensuring the performance of the source-drain doped layer 300, and further being beneficial for improve the working performance of the semiconductor structure.

For example, in one embodiment, the inner spacer 700 may protrude from the sidewall of the channel layer 220 into the source-drain doped layer 300.

It should be noted that in one embodiment, along the extension direction of the channel layer structure 230, the dimension d of the inner spacer 700 embedded in the source-drain doped layer 300 should not be excessively large or small. If the dimension d of the inner spacer 700 embedded in the source-drain doped layer 300 is excessively large, it may easily occupy excessive space of the source-drain doped layer 300, thereby affecting the performance of the source-drain doped layer 300. In addition, during the fabrication of the semiconductor structure, the inner spacer 700 may be formed in the source-drain doped layer 300. If the dimension d of the inner spacer 700 embedded in the source-drain doped layer 300 is excessively large, it may easily cause difficulty in forming the inner spacer 700 embedded in the source-drain doped layer 300, thereby affecting the fabrication of the inner spacer 700. If the dimension d of the inner spacer 700 embedded in the source-drain doped layer 300 is excessively small, the isolation effect of the inner spacer 700 between the stacked layer gate 610 and the source-drain doped layer 300 may be easily affected, thereby affecting the performance of the semiconductor structure.

Therefore, in one embodiment, along the extension direction of the channel layer structure 230, the dimension d of the inner spacer 700 embedded in the source-drain doped layer 300 may be about 1 Å to 50 Å.

In one embodiment, the inner spacer 700 may be an air spacer 710.

If the air spacer 710 is configured as the inner spacer 700, after forming a groove in the source-drain doped layer 300, the gate structure 600 may be directely formed, and then the air space in the groove may be configured as the air spacer 710. The fabrication steps may be simple and easy to implement, which may be beneficial for easily obtaining the inner spacer 700 while ensuring the performance of the source-drain doped layer 300.

In one embodiment, the semiconductor structure may further include gate spacers 500 covering the sidewalls of the gate structure 600 crossing the channel layer structure 230.

The gate spacers 500 may be configured to protect the sidewalls of the gate structure 600.

In one embodiment, the gate spacer 500 may be a single-layer structure or a stacked layer structure. The gate spacer 500 may be made of a material including silicon oxide, silicon nitride, silicon carbide, silicon carbon nitride, silicon carbon nitrogen oxide, silicon nitrogen oxide, boron nitride, and boron carbon nitride and/or a combination thereof.

In one embodiment, the semiconductor structure may further include a dielectric layer 400 covering the sidewalls of the gate structure 600 and a source-drain doped layer 300.

The dielectric layer 400 may be configured as a process platform for forming the gate structure 600.

For example, in one embodiment, the dielectric layer 400 may cover the sidewalls of the gate spacers 500.

In one embodiment, the dielectric layer 400 may be made of an insulating material, including silicon oxide, silicon nitride, silicon oxygen nitride, silicon carbon oxide, silicon carbon nitride, silicon carbon nitrogen oxide, and/or a combination thereof.

FIG. 6 illustrates a structural schematic of another exemplary semiconductor structure according to various disclosed embodiments of the present disclosure.

The similarity between one embodiment and above-mentioned embodiments are not be described in detail herein. The difference between one embodiment and above-mentioned embodiments is that the inner spacer may be a dielectric spacer.

Referring to FIG. 6, the inner spacer 700 may be a dielectric spacer 720.

The inner spacer 700 may be configured to isolate the stacked layer gate 610 and the source-drain doped layer 300. Using the dielectric spacer 720 as the inner spacer 700 may desirably reduce the parasitic capacitance between the gate structure 600 and the source-drain doped layer 300.

In one embodiment, the dielectric spacer 720 may be made of a material including a dielectric material. The dielectric material may desirably isolate the gate structure 600 and the source-drain doped layer 300.

For example, in one embodiment, the dielectric spacer 720 may be made of a material including SiN, SiON, SiOCN, SiOC or SiOCH. The k value of SiN, SiON, SiOCN, SiOC or SiOCH may be relatively small, which may be beneficial for desirably isolating the gate structure 600 and the source-drain doped layer 300 and reducing the parasitic capacitance between the gate structure 600 and the source-drain doped layer 300.

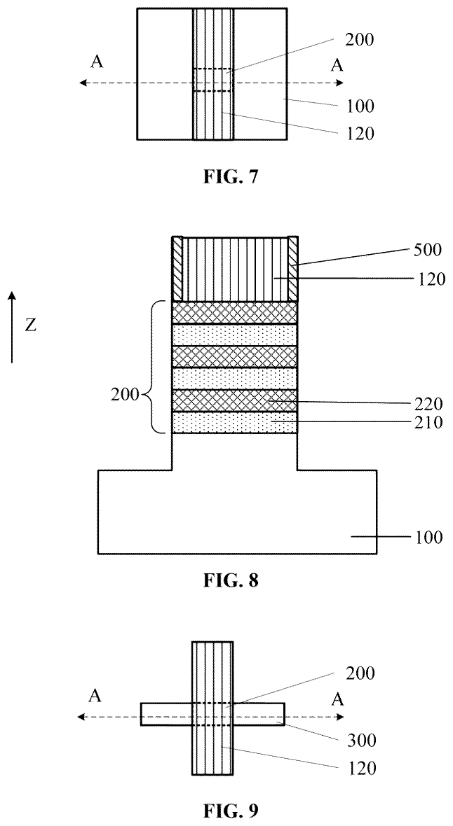

FIGS. 7-14 illustrate structural schematics corresponding to certain stages of an exemplary fabrication method of a semiconductor structure according to various disclosed embodiments of the present disclosure.

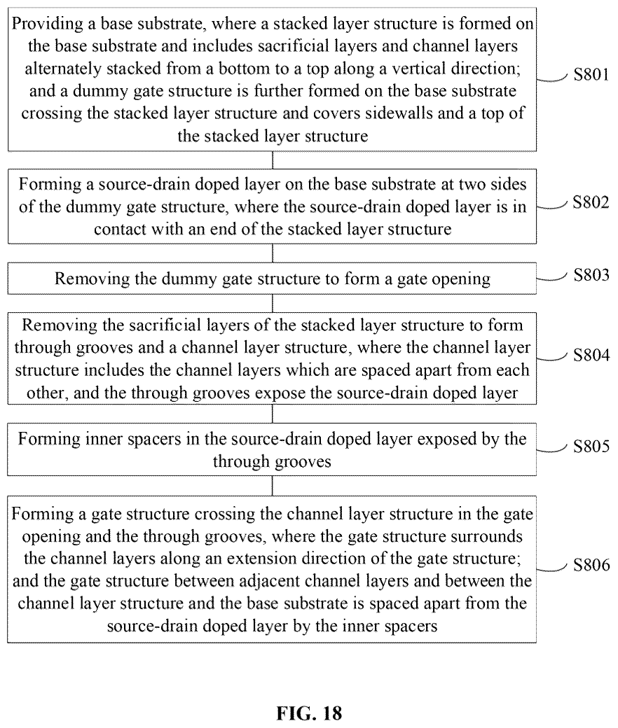

Referring to FIGS. 7-8, FIG. 7 illustrates a top view of a dummy gate structure, a base substrate and a stacked layer structure; and FIG. 8 illustrates a cross-sectional view along an AA direction in FIG. 7. The base substrate 100 may be provided; a stacked layer structure 200 may be formed on the base substrate 100; the stacked layer structure 200 may include sacrificial layers 210 and channel layers 220 alternately stacked from bottom to top along the vertical direction (as shown as the Z direction in FIG. 8); a dummy gate structure 120 crossing the stacked layer structure 200 may be also formed on the base substrate 100; and the dummy gate structure 120 may cover the sidewalls and the top of the stacked layer structure 200 (e.g., in S801 of FIG. 18).

The base substrate 100 may provide a process operation basis for the fabrication process of the semiconductor structure. The semiconductor structure may include gate-all-around (GAA) transistors and fork-sheet gate transistors.

In one embodiment, the base substrate 100 may be made of silicon. In other embodiments, the base substrate may also be made of other materials including germanium, silicon germanium, silicon carbide, gallium arsenide, indium gallium and/or the like. The base substrate may also be made of other types of substrates including a silicon-on-insulator substrate, a germanium-on-insulator substrate and/or the like. The material of the base substrate may be a material suitable for process needs or easy to integrate.

The channel layer 220 of the stacked layer structure 200 may be configured as the channel of the semiconductor structure. The sacrificial layer 210 may be configured to provide a process basis for subsequent implementation of the suspended arrangement of the channel layer 220, and may be also configured to occupy spatial position for subsequently formed gate structure. In the subsequent process, the sacrificial layer 210 may be removed, such that the channel layer 220 may be suspended; and the gate structure may be formed between the channel layer 220 and the base substrate 100, and between adjacent channel layers 220.

The surface of the channel layer 220 covered by the gate structure may be configured as the channel. In one embodiment, the top, the bottom and the sidewalls of the channel layer 220 may all be configured as channels, which may increases the area of the channel layer 220 configured as the channels, thereby increasing the operating current of the semiconductor structure.

In one embodiment, in the process of providing the base substrate 100, the channel layer 220 may be made of a material including silicon, germanium, silicon germanium, group III-V semiconductor materials or the like. Exemplarily, the channel layer 220 may be made of silicon. In other embodiments, the material of the channel layer may be determined based on the type and performance of the transistor.

In one embodiment, in the process of providing the base substrate 100, the sacrificial layer 210 may be made of a material including silicon germanium.

The etching resistance of silicon germanium may be lower than the etching resistance of silicon, and silicon germanium may form a relatively large etching selectivity ratio with silicon. Therefore, in the subsequent process of removing the sacrificial layer 210, the sacrificial layer 210 may easily be removed, and the damage to the channel layer 220 may be reduced when the sacrificial layer 210 is removed.

In other embodiments, according to the material of the channel layer, the second sacrificial layer may be selected from materials having an etching selectivity ratio suitable for the channel layer, such that when the second sacrificial layer is subsequently removed, the damage to the channel layer may be reduced.

In one embodiment, in the process of providing the base substrate 100, along the extension direction of the stacked layer structure 200, an active source-drain doped layer 300 may be formed on the isolation layer 210 on two sides of the stacked layer structure 200; and the source-drain doped layer 300 may be in contact with the end of the stacked layer structure 200 (e.g., in S802 of FIG. 18).

The dummy gate structure 120 may be configured to occupy spatial position for subsequent fabrication of the gate structure.

In one embodiment, the dummy gate structure 120 may be a stacked layer structure, including a dummy gate oxide layer (not shown) and a dummy gate layer (not shown) covering the dummy gate oxide layer.

Exemplarily, in one embodiment, the dummy gate oxide layer may be made of silicon oxide, and the dummy gate layer may be made of polysilicon.

In one embodiment, during the process of providing the base substrate 100, gate spacers 500 may be also formed on the sidewalls of the dummy gate structure 120 crossing the stacked layer structure 200.

The gate spacers 500 may be configured to protect the sidewalls of the gate structure subsequently formed.

In one embodiment, the gate spacer 500 may be a single-layer structure or a stacked layer structure. The gate spacer 500 may be made of a material including silicon oxide, silicon nitride, silicon carbide, silicon carbon nitride, silicon carbon nitrogen oxide, silicon nitrogen oxide, boron nitride, and boron carbon nitride and/or a combination thereof.

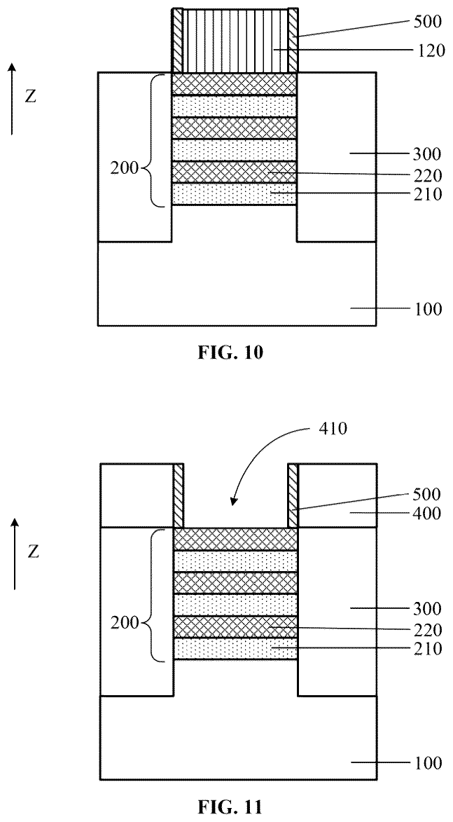

Referring to FIGS. 9-10, FIG. 9 illustrates a top view of the dummy gate structure, the stacked layer structure, and the source-drain doped layer; and FIG. 10 illustrates a cross-sectional view along an AA direction in FIG. 9. The source-drain doped layer 300 may be formed on the base substrate 100 on two sides of the dummy gate structure 120. Along the extension direction of the stacked layer structure 200, the source-drain doped layer 300 may be in contact with the end of the stacked layer structure 200.

The source-drain doped layer 300 may be configured as the source region or the drain region of the transistor. For example, the doped type of the source-drain doped layer 300 may be same as the channel conductivity type of corresponding transistor.

For example, when the base substrate 100 is configured to form an NMOS (N-channel metal-oxide semiconductor) transistor, the doped ions in the source-drain doped layer 300 may be N-type ions; and the N-type ions may include P ions, As ions or Sb ions; and when the base substrate 100 is configured to form a PMOS (P-channel metal-oxide semiconductor) transistor, the doped ions in the source-drain doped layer 300 may be P-type ions; and the P-type ions may include B ions, Ga ions or In ions.

In one embodiment, the source-drain doped layer 300 may be grown based on the sidewalls of the stacked layer structure 200, and then the inner spacers may be formed. Compared with the solution of forming the inner spacers first, and then growing the source-drain doped layer based on the inner spacers and the channel layers, the solution provided in the present disclosure may be beneficial for avoiding the difficulty of growth based on the inner spacers which may result in the fabrication of grain boundary in the source-drain doped layer 300 to affect the stress, thereby being beneficial for improving the growth quality of the source-drain doped layer 300, ensuring the performance of the source-drain doped layer 300, and further being beneficial for improve the working performance of the semiconductor structure.

In one embodiment, an epitaxial growth process may be configured to form the source-drain doped layers 300 on the base substrate 100 on two sides of the dummy gate structure 120.

The epitaxial growth process may desirably control the process parameters, the process controllability may be high, and more accurate thickness dimension of the source-drain doped layer 300 may be easily obtained. Moreover, the epitaxial growth process may be easy to form a film layer with less impurities, such that the film quality of the source-drain doped layer 300 may be relatively high.

Moreover, in one embodiment, the source-drain doped layer 300 may be epitaxially grown based on the sidewalls of the stacked layer structure 200. The channel layer 220 may be made of silicon, and the sacrificial layer 210 may be made of silicon germanium, such that desirable epitaxial growth may be performed on the surfaces of silicon and silicon germanium. Therefore, the sidewalls of the stacked layer structure 200 may be configured as growth basis for epitaxial growth of the source-drain doped layer 300 to obtain desirable film quality, which may be beneficial for ensuring performance of the source-drain doped layer 300.

Referring to FIG. 11, before subsequent removal of the dummy gate structure 120 to form a gate opening, the fabrication method may further include forming a dielectric layer 400 covering the sidewalls of the dummy gate structure 120 and the source-drain doped layer 300.

The dielectric layer 400 may be configured to provide a process platform for subsequent fabrication of the gate structure.

For example, in one embodiment, the dielectric layer 400 may cover the sidewalls of the gate spacers 500.

In one embodiment, the dielectric layer 400 may be made of an insulating material, including silicon oxide, silicon nitride, silicon oxygen nitride, silicon oxygen carbide, silicon nitrogen carbide, silicon oxygen nitrogen carbide, and/or a combination thereof.

Referring to FIG. 11, the dummy gate structure 120 may be removed to form a gate opening 410 (e.g., in S803 of FIG. 18).

The gate opening 410 may be configured to provide spatial position for subsequent fabrication of the gate structure.

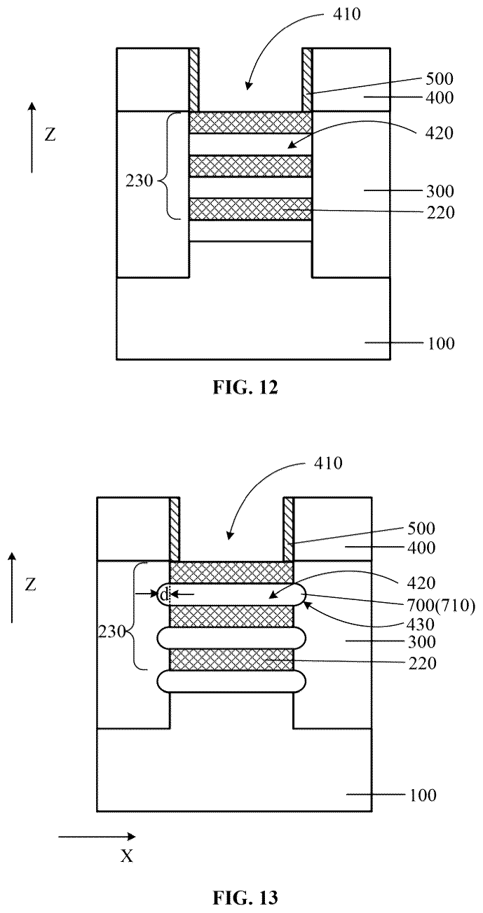

Referring to FIG. 12, the sacrificial layer 210 of the stacked layer structure 200 may be removed to form a through-groove 420; a plurality of channel layers 220 spaced apart from each other may form the channel layer structure 230; and the through-groove 420 may expose the source-drain doped layer 300 (e.g., in S804 of FIG. 18).

The through-groove 420 may be configured to provide spatial position for subsequent fabrication of the gate structure and provide a channel for subsequent fabrication of the inner spacers; and the through-groove 420 may expose the source-drain doped layer 300 to prepare for subsequent fabrication of inner spacers in the source-drain doped layer 300.

In one embodiment, an isotropic etching process may be configured to remove the sacrificial layer 210 of the stacked layer structure 200 to form the through-groove 420.

The process cost of the isotropic etching process may be relatively low, the operation may be simple, and a large etching selectivity ratio may be realized, which may be beneficial for reducing damage to the surface of the channel layer 220 and the surface of the source-drain doped layer 300 during the process of removing the sacrificial layer 210.

It should be noted that in one embodiment, in the process of removing the sacrificial layer 210 of the stacked layer structure 200 to form the through-groove 420, the etching selectivity ratio between the sacrificial layer 210 and the source-drain doped layer 300 should not be excessively small. If the etching selectivity ratio between the sacrificial layer 210 and the source-drain doped layer 300 is excessively small, the source-drain doped layer 300 may be easily damaged during the removal of the sacrificial layer 210. Therefore, in the process of removing the sacrificial layer 210 of the stacked layer structure 200 to form the through-groove 420, the etching selectivity ratio between the sacrificial layer 210 and the source-drain doped layer 300 may be greater than or equal to 10.

It should also be noted that in one embodiment, in the process of removing the sacrificial layer 210 of the stacked layer structure 200 to form the through-groove 420, the etching selectivity ratio between the sacrificial layer 210 and the channel layer 220 should not be excessively small. If the etching selectivity ratio between the sacrificial layer 210 and the channel layer 220 is excessively small, the channel layer 220 may be easily damaged during the removal of the sacrificial layer 210. Therefore, in the process of removing the sacrificial layer 210 of the stacked layer structure 200 to form the through-groove 420, the etching selectivity ratio between the sacrificial layer 210 and the channel layer 220 may be greater than or equal to 10.

Referring to FIG. 13, the inner spacer 700 may be formed in the source-drain doped layer 300 exposed by the through-groove 420 (e.g., in S805 of FIG. 18).

The inner spacere 700 may be configured to isolate the gate structure subsequently formed and the source-drain doped layer 300 to reduce the parasitic capacitance between the gate structure and the source-drain doped layer 300.

In one embodiment, forming the inner spacer 700 in the source-drain doped layer 300 exposed by the through-groove 420 may include, along the extension direction of the channel layer structure 230 (shown as the X direction in FIG. 13), removing a part of the source-drain doped layer 300 via the through-groove 420, and forming a groove 430 connected to the through-groove 420 and extending into the source-drain doped layer 300.

The groove 430 may be configured to provide spatial position for the fabrication of the inner spacer 700.

It should be noted that in one embodiment, in the process of removing a part of the source-drain doped layer 300 via the through-groove 420 along the extension direction of the channel layer structure 230 and forming the groove 430 connected to the through-groove 420 and extending into the source-drain doped layer 300, the dimension d of the source-drain doped layer 300 removed along the extension direction of the channel layer structure 230 should not be excessively large or small. If the dimension d of the removed source-drain doped layer 300 is excessively large, it may easily result in excessive space for removing the source-drain doped layer 300 and affect performance of the source-drain doped layer 300. Moreover, if the dimension d of the removed source-drain doped layer 300 is excessively large, it may also be difficult to remove a part of the source-drain doped layer 300 and affect the fabrication of the groove 430. If the dimension d of the removed source-drain doped layer 300 is excessively small, the inner spacer obtained through the groove 430 may be excessively thin, which may easily affect subsequent isolation effect between the gate structure and the source-drain doped layer 300 by the inner spacer and affect performance of the semiconductor structure. Therefore, in the process of removing a part of the source-drain doped layer 300 via the through-groove 420 along the extension direction of the channel layer structure 230 and forming the groove 430 connected to the through-groove 420 and extending into the source-drain doped layer 300, the dimension d of the source-drain doped layer 300 removed along the extension direction of the channel layer structure 230 may be about 1 Å to 50 Å.

In one embodiment, an isotropic etching process may be configured to remove a part of the source-drain doped layer 300 via the through-groove 420 along the extension direction of the channel layer structure 230 and form the groove 430 connected to the through-groove 420 and extending into the source-drain doped layer 300.

The process cost of the isotropic etching process may be relatively low, the operation may be simple, and a large etching selectivity ratio may be realized, which may be beneficial for reducing damage to the surface of the channel layer 220 during the process of removing a part of the source-drain doped layer 300.

It should be noted that in one embodiment, in the process of removing a part of the source-drain doped layer 300 via the through-groove 420 along the extension direction of the channel layer structure 230 and forming the groove 430 connected to the through-groove 420 and extending into the source-drain doped layer 300, the etching selectivity ratio between the source-drain doped layer 300 and the channel layer 220 should not be excessively small. If the etching selectivity ratio between the source-drain doped layer 300 and the channel layer 220 is excessively small, the channel layer 220 may be easily damaged in the processing of removing a part of the source-drain doped layer 300. Therefore, in one embodiment, in the process of removing a part of the source-drain doped layer 300 via the through-groove 420 along the extension direction of the channel layer structure 230 and forming the groove 430 connected to the through-groove 420 and extending into the source-drain doped layer 300, the etching selectivity ratio between the source-drain doped layer 300 and the channel layer 220 may be greater than or equal to 10.

In one embodiment, the space remained in the groove 430 may form the air spacer 710 as the inner spacer 700.

If the air spacer 710 is configured as the inner spacer 700, the gate structure may be directly formed subsequently to retain the air space in the groove 430 as the air spacer 710.

The fabrication steps may be simple and easy to implement, which may be beneficial for obtaining the inner spacer 700 simply and easily while ensuring the performance of the source-drain doped layer 300.

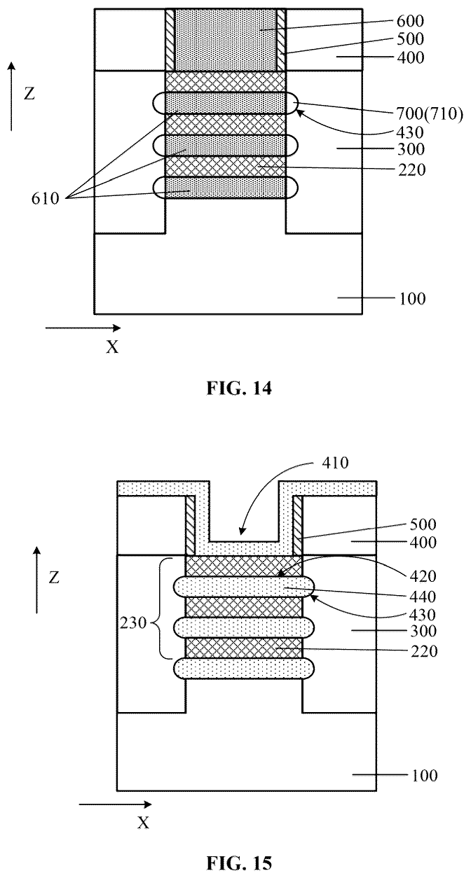

Referring to FIG. 14, the gate structure 600 crossing the channel layer structure 230 may be formed in the gate opening 410 and the through-groove 420; the gate structure 600 may surround the channel layer 220 along the extension direction of the gate structure 600; and the gate structure 600 between adjacent channel layers 220 and between the channel layer structure 230 and the base substrate 100 may be spaced apart from the source-drain doped layer 300 by the inner spacers 700 (e.g., in S806 of FIG. 18).

The gate structure 600 may be configured to control the turn-on and turn-off of the channel of the transistor.

The gate structure 600 may surround and cover the channel layer 220. Therefore, the top, the bottom and the sidewalls of the channel layer 220 may all be configured as the channels, which may increase the area of the channel layer 220 configured as the channels, thereby increasing operating current of the semiconductor structure.

In one embodiment, the gate structure 600 may include a gate dielectric layer surrounding the channel layer 220 along the extension direction of the gate structure 600, and a gate electrode layer on the gate dielectric layer.

The gate dielectric layer may be configured to isolate the gate electrode layer and the channel layer 220, and isolate the gate electrode layer and the base substrate 100.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the high-k gate dielectric layer may be made of a material including a high-k dielectric material. The high-k dielectric material may refer to a dielectric material with relative dielectric constant greater than relative dielectric constant of silicon oxide. In one embodiment, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel layer 220. For example, the gate oxide layer may be made of silicon oxide.

In one embodiment, the gate structure 600 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may only include the work function layer.

In other embodiments, according to process requirements, the gate structure may also be a polysilicon gate structure.

In one embodiment, in the process of forming the gate structure 600 crossing the channel layer structure 230 in the gate opening 410 and the through-groove 420, the sidewalls of the gate structure 600 between adjacent channel layers 220 and between the channel layer structure 230 and the base substrate 100 may be coplanar with the sidewalls of the channel layer 220.

The gate structure 600 between adjacent channel layers 220 and between the channel layer structure 230 and the base substrate 100 may be configured as the stacked layer gate 610. If the sidewalls of the stacked layer gate 610 are coplanar with the sidewalls of the channel layer 220, along the extension direction of the channel layer structure 230, it is beneficial for increasing the coverage area of the channel layer 220 by the stacked layer gate 610 and improving the control ability of the stacked layer gate 610 over the channel. In addition, the area configured as the channel in the channel layer 220 may be increased, which may be beneficial for increasing operating current of the semiconductor structure. Moreover, the sidewalls of the stacked layer gate 610 are coplanar with the sidewalls of the channel layer 220, which may be beneficial for ensuring the space that the sidewalls of the stacked layer gate 610 are at the inner spacers 700 in the source-drain doped layer 300, thereby being beneficial for ensuring the isolation effect of the inner spacers 700.

It should be noted that in one embodiment, according to actual process requirements, the fabrication process rate of the gate structure 600 may be relatively fast, which may be beneficial for preventing the gate structure 600 from being filled into the groove 430, thereby being beneficial for ensuring sufficient space for the air spacer 710 in the groove 430.

FIGS. 15-17 illustrate structural schematics corresponding to certain stages of another exemplary fabrication method of a semiconductor structure according to various disclosed embodiments of the present disclosure.

The similarity between one embodiment and above-mentioned embodiments may not be described in detail herein. The difference between one embodiment and above-mentioned embodiments may be that a dielectric spacer may be formed in the groove to configured as the inner spacer.

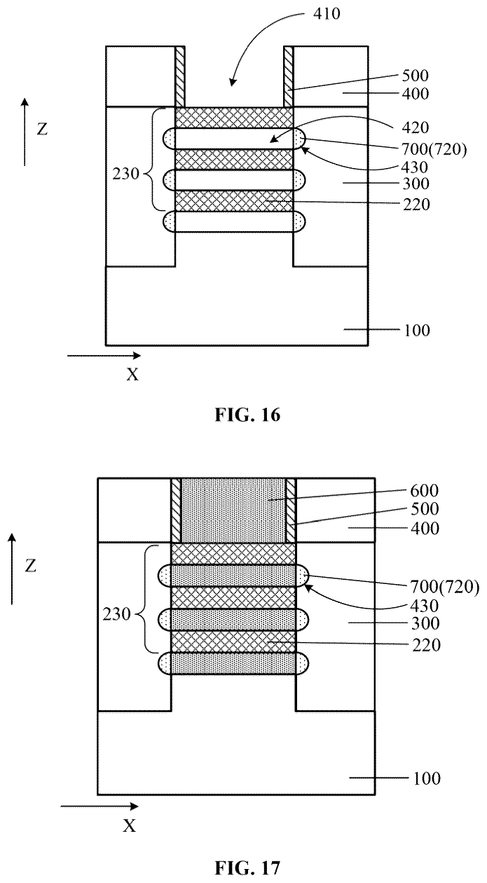

Referring to FIGS. 15-16, the dielectric spacer 720 may be formed in the groove 430, which may be configured as the inner spacer 700.

The inner spacer 700 may be configured to isolate the gate structure 600 and the source-drain doped layer 300. Using the dielectric spacer 720 as the inner spacer 700 may desirably reduce the parasitic capacitance between the gate structure 600 and the source-drain doped layer 300.

In one embodiment, the dielectric spacer 720 may be made of a material including a dielectric material. The dielectric material may desirably isolate the gate structure 600 and the source-drain doped layer 300.

For example, in one embodiment, the dielectric spacer 720 may be made of a material including SiN, SiON, SiOCN, SiOC or SiOCH. The k value of SiN, SiON, SiOCN, SiOC or SiOCH may be relatively small, which may be beneficial for desirably isolating the gate structure 600 and the source-drain doped layer 300 and reducing the parasitic capacitance between the gate structure 600 and the source-drain doped layer 300.

For example, referring to FIG. 15, forming the dielectric spacer 720 in the groove 430 may include forming a dielectric material layer 440 covering the bottom and sidewalls of the gate opening 410 and filling the through-groove 420 and the groove 430.

The dielectric material layer 440 may be configured to directly form the dielectric spacer 720.

In one embodiment, an atomic layer deposition process may be configured to form the dielectric material layer 440 covering the bottom and sidewalls of the gate opening 410 and filling the through-groove 420 and the groove 430.

The atomic layer deposition process has desirable step coverage capability, such that the dielectric material layer 440 may desirably cover the bottom and sidewalls of the gate opening 410 and fill the through-groove 420 and the groove 430. The thickness uniformity of the dielectric material layer 440 formed by the atomic layer deposition process may be desirable, thereby being beneficial for thickness uniformity of formed dielectric spacer 720.

Referring to FIG. 16, the dielectric material layer 440 covering the bottom and sidewalls of the gate opening 410 and in the through-groove 420 may be removed, and the dielectric material layer 440 in the groove 430 may be retained as the dielectric spacer 720.

In one embodiment, the isotropic etching process may be configured to remove the dielectric material layer 440 covering the bottom and sidewalls of the gate opening 410 and the through-groove 420.

The process cost of the isotropic etching process may be relatively low, the operation steps may be simple, and a relatively large etching selectivity ratio may be realized, which may be beneficial for reducing damage to the surface of the channel layer 220 during the removal of the dielectric material layer 440. Moreover, the process parameter of the isotropic etching process may be easy to control, which may be beneficial for retaining the dielectric material layer 440 in the groove 430 as the dielectric spacer 720 by controlling the process parameter.

It should be noted that in one embodiment, in the process of removing the dielectric material layer 440 covering the bottom and sidewalls of the gate opening 410 and in the through-groove 420, the etching selectivity ratio between the dielectric material layer 440 and the channel layer 220 should not be excessively small. If the etching selectivity ratio between the dielectric material layer 440 and the channel layer 220 is excessively small, the channel layer 220 may be easily damaged during the removal of the dielectric material layer 440. Therefore, in one embodiment, in the process of removing the dielectric material layer 440 covering the bottom and sidewalls of the gate opening 410 and in the through-groove 420, the etching selectivity ratio between the dielectric material layer 440 and the channel layer 22 may be greater than or equal to 10.

Referring to FIG. 17, the gate structure 600 crossing the channel layer structure 230 in the gate opening 410 and the through-groove 420 may be formed; the gate structure 600 may surround the channel layer 220 along the extension direction of the gate structure 600; and the gate structure 600 between adjacent channel layers 220 and between the channel layer structure 230 and the base substrate 100 may be spaced apart from the source-drain doped layer 300 by the the inner spacers 700.

In one embodiment, the gate structure 600 may be in contact with the dielectric spacer 720.

It should be noted that in other embodiments, the space of a part of the grooves may be retained to form the air spacers, and dielectric spacers may be formed in remained part of the grooves.

Although the present disclosure has been disclosed above, the present disclosure is not limited thereto. Any changes and modifications may be made by those skilled in the art without departing from the spirit and scope of the disclosure, and the scope of the disclosure should be determined by the scope defined by the appended claims.

What is claimed is:

1. A semiconductor structure, comprising:
a base substrate;
a channel layer structure, disposed above the base substrate, wherein the channel layer structure includes one or more channel layers spaced apart from each other;
a gate structure, on the base substrate and crossing the channel layer structure, wherein the gate structure surrounds the one or more channel layers along an extension direction of the gate structure; and a gate structure between adjacent channel layers and between the channel layer structure and the base substrate is configured as a stacked layer gate;
a source-drain doped layer, on the base substrate at two sides of the gate structure and in contact with an end of the channel layer structure; and
inner spacers, at a sidewall of the stacked layer gate and embedded in the source-drain doped layer, wherein the stacked layer gate and the source-drain doped layer are spaced apart by the inner spacers.

2. The semiconductor structure according to claim 1, wherein:
the sidewall of the stacked layer gate is coplanar with a sidewall of a channel layer.

3. The semiconductor structure according to claim 1, wherein:
along an extension direction of the channel layer structure, a dimension of the inner spacers embedded in the source-drain doped layer is from about 1 Å to about 50 Å.

4. The semiconductor structure according to claim 1, wherein:
the inner spacers include air spacers, dielectric spacers, and/or a combination thereof.

5. A fabrication method of a semiconductor structure, comprising:
providing a base substrate, wherein a stacked layer structure is formed on the base substrate and includes sacrificial layers and channel layers alternately stacked from a bottom to a top along a vertical direction; and a dummy gate structure is further formed on the base substrate crossing the stacked layer structure and covers sidewalls and a top of the stacked layer structure;
forming a source-drain doped layer on the base substrate at two sides of the dummy gate structure, wherein the source-drain doped layer is in contact with an end of the stacked layer structure;
removing the dummy gate structure to form a gate opening;
removing the sacrificial layers of the stacked layer structure to form through-grooves and a channel layer structure, wherein the channel layer structure includes the channel layers which are spaced apart from each other, and the through-grooves expose the source-drain doped layer;
forming inner spacers in the source-drain doped layer exposed by the through-grooves; and
forming a gate structure crossing the channel layer structure in the gate opening and the through-grooves, wherein the gate structure surrounds the channel layers along an extension direction of the gate structure; and the gate structure between adjacent channel layers and between the channel layer structure and the base substrate is spaced apart from the source-drain doped layer by the inner spacers.

6. The fabrication method according to claim 5, wherein:
the gate structure crossing the channel layer structure is formed in the gate opening and the through-grooves, such that sidewalls of the gate structure between adjacent channel layers and between the channel layer structure and the base substrate are coplanar with sidewalls of the channel layers.

7. The fabrication method according to claim 5, wherein forming the inner spacers in the source-drain doped layer exposed by the through-grooves includes:
along an extension direction of the channel layer structure, removing a part of the source-drain doped layer via the through-grooves, and forming grooves connected to the through-grooves and extending into the source-drain doped layer; and
retaining a space of the grooves to form air spacers configured as the inner spacers; or forming dielectric spacers in the grooves as the inner spacers.

8. The fabrication method according to claim 7, wherein:
along the extension direction of the channel layer structure, the part of the source-drain doped layer is removed via the through-grooves, and the grooves connected to the through-grooves and extending into the source-drain doped layer are formed, such that a dimension of the removed part of the source-drain doped layer is about 1 Å to 50 Å along the extension direction of the channel layer structure.

9. The fabrication method according to claim 7, wherein:
using an isotropic etching process, along the extension direction of the channel layer structure, the part of the source-drain doped layer is removed via the through-grooves, and the grooves connected to the through-grooves and extending into the source-drain doped layer are formed.

10. The fabrication method according to claim 7, wherein:
for removing the part of the source-drain doped layer via the through-grooves along the extension direction of the channel layer structure, an etching selectivity ratio between the source-drain doped layer and the channel layers is greater than or equal to 10.

11. The fabrication method according to claim 7, wherein:
forming the inner spacers in the source-drain doped layer exposed by the through-grooves includes forming the dielectric spacers in the grooves as the inner sidewalls; and
forming the dielectric spacers in the grooves includes forming a dielectric material layer covering a bottom and sidewalls of the gate opening and filling the through-grooves and the grooves; and includes removing the dielectric material layer covering the bottom and the sidewalls of the gate opening and in the through-grooves and retaining the dielectric material layer in the grooves as the dielectric spacers.

12. The fabrication method according to claim 11, wherein:
an atomic layer deposition process is configured to form the dielectric material layer covering the bottom and the sidewalls of the gate opening and filling the through-grooves and the grooves.

13. The fabrication method according to claim 11, wherein:
an isotropic etching process is configured to remove the dielectric material layer covering the bottom and the sidewalls of the gate opening and the through-grooves.

14. The fabrication method according to claim 11, wherein:
for removing the dielectric material layer covering the bottom and the sidewalls of the gate opening and the through-grooves, an etching selectivity ratio between the dielectric material layer and the channel layers is greater than or equal to 10.

15. The fabrication method according to claim 5, wherein:
for removing the sacrificial layers of the stacked layer structure to form the through-grooves, an etching selectivity ratio between the sacrificial layers and the source-drain doped layer is greater than or equal to 10, and an etching selectivity ratio between the sacrificial layers and the channel layers is greater than or equal to 10.

16. The fabrication method according to claim 5, wherein:
an epitaxial growth process is configured to form the source-drain doped layer on the base substrate at two sides of the dummy gate structure.

17. The fabrication method according to claim 5, wherein:
in a step of providing the base substrate, the channel layers are made of a material including silicon, germanium, silicon germanium or a group III-V semiconductor material; and the sacrificial layers are made of silicon germanium.
